(19) United States
(12) Patent Application Publication
(10) Pub. No.: US 2024/0347779 A1
(43) Pub. Date: Oct. 17, 2024

(54) DEVICE FOR DETECTING LEAKS FOR MOTOR VEHICLE BATTERY PACK

(71) Applicant: ATEQ, Les Clayes-sous-Bois (FR)

(72) Inventors: Patrick Serra, Les Clayes-sous-Bois (FR); Jean-Luc Regef, Les Clayes-sous-Bois (FR)

(21) Appl. No.: 18/292,265

(22) PCT Filed: Jul. 13, 2022
(86) PCT No.: PCT/EP2022/069683

§ 371 Date: Jan. 25, 2024

(30) Foreign Application Priority Data
Jul. 27, 2021 (FR) 2108139

(51) Int. Cl. H01M 10/42; G01M 3/32

(52) U.S. Cl. CPC H01M 10/4228; G01M 3/3209; H01M 2220/20

(57) ABSTRACT

The present invention relates to a device (1) for detecting leaks for a motor vehicle battery pack, said device (1) comprising:—a pneumatic circuit (100) comprising a plurality of valves (V₁, V₂, V₃) and a pressure sensor (106);—at least one connector (7) allowing to connect said pneumatic circuit (100) to at least one element of the battery pack; said device (1) being configured to carry out at least one procedure for detecting leaks on at least one element of the battery pack via said pneumatic circuit (100) and said connector (7).

The present invention relates to the field of devices for detecting leaks (or measuring sealing) for motor vehicle battery packs.

It is noted that “battery pack” means traction and/or operating batteries, generally accompanied by a system for thermal management of said battery, which are intended to be on board electric and hybrid vehicles. The thermal management system is for example a network of fluid ducts allowing to cool or to heat the battery as needed.

These batteries, generally of the lithium-ion type, are disposed in specific cases (such as a rigid envelope), these cases generally integrating the thermal management system, the whole thus forming a battery pack for a motor vehicle.

With the spread of hybrid and electric vehicles, and the fact that these battery packs must be tested, diagnosed and maintained over time and as they are used, it is becoming necessary to have equipment adapted to maintaining and repairing said battery packs, in particular in garages and repair workshops.

More particularly, there is a demand from manufacturers and mechanics to have a simple, easy to use and effective device for detecting leaks that allows to test the sealing of a battery pack after the latter has been repaired or serviced/maintained (in particular to test the sealing of the case in which components of the battery and/or of the thermal management system of said battery are housed).

The presence of leaks in the case of the battery and/or of the thermal management system can have dramatic consequences, or at the very least reduce the efficiency and/or the service life of the battery. Moreover, this type of device, intended for a garage or industrial environment, must therefore be robust, easy to use, not very costly, easy to transport and to use by any operator, trained or not.

The invention is thus a device for detecting leaks for a motor vehicle battery pack, said device comprising:
a pneumatic circuit comprising a plurality of valves and a pressure sensor;
at least one connector allowing to connect said pneumatic circuit to at least one element of the battery pack;
said device being configured to operate at least one procedure for detecting leaks on at least one element of the battery pack via the pneumatic circuit and the connector.

The invention is thus a device for detecting leaks for a motor vehicle battery pack, said device comprising:
a pneumatic circuit comprising a plurality of valves, a pressure sensor and a pump;
at least one connector allowing to connect said circuit to at least one element of the battery pack;
said device being configured to operate at least one procedure for detecting leaks on at least one element of the battery pack via the pneumatic circuit and the connector.

It is noted that the device according to the invention can thus test the presence of leaks in one or more elements of a battery pack, more particularly the sealing of the case of the battery and/or of the thermal management system of the battery.

According to one possible feature, the pneumatic circuit comprises a pump (or a compressor), said pneumatic circuit being configured to operate procedures for detecting leaks under pressure and/or under vacuum.

According to one possible feature, said pneumatic circuit is configured to operate procedures for detecting leaks under pressure and/or under vacuum.

Said device according to the invention is thus configured to carry out tests under pressure or under vacuum, that is to say by positively or negatively varying the pressure in the volume, the sealing of which it is desired to test. Advantageously, there is only a single pump or compressor, the pneumatic circuit being configured to fill or empty the element of the battery pack to be tested.

According to another possible feature, said device is configured to generate a relative pressure ranging from −1 to 3 bar (in particular via the pump).

According to another possible feature, said pump has a flow rate of between 10 and 100 L/min (litres per minute), and preferably between 15 and 30 L/min.

According to another possible feature, the device comprises a database relative to procedures for detecting leaks in motor vehicle battery packs. Advantageously, the database on board the device allows the operator to select a detection procedure adapted to the element of the battery pack, the sealing of which it is desired to test.

According to another possible feature, said database comprises one or more of the following pieces of data: vehicle model(s) and/or battery model(s) associated with at least one procedure for detecting leaks.

The database of the device advantageously includes a list of the motor vehicle models and/or of the battery pack models to allow the operator to quickly find the most suitable procedure for detecting leaks and to avoid the necessity of having to configure the various parameters of a procedure for detecting leaks. The leak procedures include in particular the acceptable leak rate values (generally expressed in cc/min or in variation of pressure per unit of time) for the element(s) of the battery pack tested, these values are generally communicated by the motor vehicle manufacturer or the battery pack manufacturer.

According to another possible feature, said at least one procedure for detecting leaks comprises one or more of the following parameters: volume of the battery and/or of the thermal management system, duration of the various steps of the leak test, test pressure, speed of filling and/or of emptying of the battery, leak threshold, flexibility coefficient of an element of the battery pack. One or more of these parameters are pre-set according to the model of the vehicle and/or of battery, thus avoiding any parameterisation for the operator before carrying out a procedure for detecting leaks.

According to another possible feature, the device comprises a man-machine interface.

Said man-machine interface (or user interface) is all of the elements allowing the user to interact with the device, and more particularly to control the device and/or to exchange information with the latter. The man-machine interface comprises for example one or more of the following elements: button(s), keyboard, screen, touch screen, wheel(s), light indicator, etc.

According to another possible feature, said device is configured to have an inclination with respect to the surface (generally horizontal) on which the device is placed so that the man-machine interface is oriented upwards.

This configuration facilitates the reading of the data on the MMI, as well as the use of the device according to the invention by the operator. It is noted that the inclination of the man-machine interface can be due either to the inclination of the front face of the device incorporating the man-machine interface or to the inclination of the case of the device (in particular via supporting lugs having different lengths).

According to one possible feature, the angle of inclination of said device is between 5 and 30 degrees, preferably between 10 and 30 degrees.

This angle range is advantageous since it is adapted to the working conditions of the user of said device.

According to another possible feature, said device comprises a plurality of magnetised support feet.

Magnetised support feet allow in particular to rigidly connect the device according to the invention to a ferromagnetic surface, thus avoiding said device moving for example after an impact or a collision.

According to another possible feature, said device comprises at least one winding support.

Said winding support allows in particular to wind a power supply cable and/or a test duct (said duct allowing to connect the device to the battery pack to be tested).

According to another possible feature, said device comprises a gripping handle.

The handle facilitates the transportation and the positioning of the device at the most suitable location for carrying out a detection of leaks.

According to another possible feature, the device comprises a module for communication (also called communication means) with a remote server, said device being configured to download from a remote server one or more of the following pieces of data: result of the leak tests, identifier of the operator having carried out the leak test, identifier of said device, identifier of the battery tested, date, measurement signals of the leak tests.

This data allows garages, battery manufacturers and/or motor vehicle manufacturers to carry out quality monitoring of the battery packs throughout their duration of use.

The data downloaded is also used to optimise the detection procedures, for example via machine learning, by generating for example modified sets of parameters based on procedures for detecting leaks carried out by devices according to the invention.

According to another possible feature, said device is configured to download, for example from a remote server, an update of the sets of parameters of one or more procedures for detecting leaks stored in the database of the device.

According to another possible feature, said parameters downloaded by the device are parameters modified after machine learning.

According to another possible feature, said device comprises a barcode reader, in particular to read and memories the identification barcode attached onto a battery pack.

According to another possible feature, said device comprises a printer. Said printer allows in particular to print a maintenance ticket after the use of the device on a battery pack. The maintenance ticket comprises for example one or more of the following pieces of information: result of the leak tests, identifier of the operator having carried out the leak test, identifier of said device, identifier of the battery tested, date and/or measurement signals of the leak tests.

According to another possible feature, the device is configured to measure and take into account the value of the back pressure during a procedure for detecting leaks on a battery pack element.

The back pressure can distort the measurement of the pressures and of the variations in pressure, invalidating the measurement of a relevant leak rate.

According to another possible feature, the back pressure value is determined, at the beginning of the detection procedure for testing the element of the battery pack tested, via measurements of the pressure, before and after the activation of the pump of the pneumatic circuit, the difference between these pressure measurements giving the value of the back pressure.

In other words, the back pressure value is determined at the moment at which the element of the battery pack tested is still empty or being filled.

It should be noted that these pressure measurements are carried out by the pressure sensor.

According to another possible feature, the device comprises one or more environment sensors to correct the measurement signals during detections of leaks.

Said environment sensors are for example one or more sensors of temperature, of atmospheric pressure, of humidity, etc.

According to another possible feature, the pressure sensor is an absolute or relative pressure sensor.

Said sensor is for example a piezoelectric pressure sensor.

The invention will be better understood, and other goals, details, features and advantages of the latter will appear more clearly during the following description of specific embodiments of the invention, given only for informational and non-limiting purposes, in reference to the appended drawings, in which:

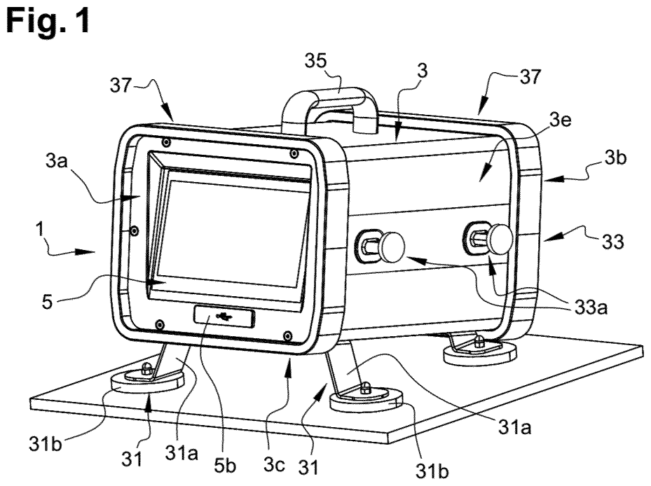

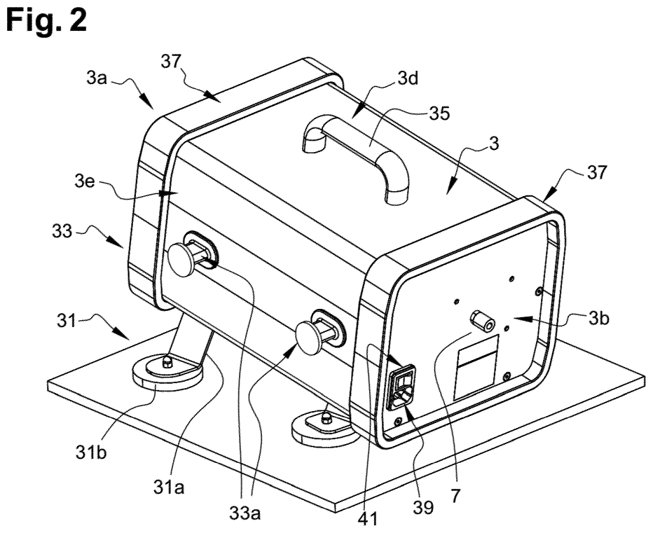

FIGS. 1 and 2, respectively labelled [FIG. 1] and [FIG. 2], are very schematic representations of a device for detecting leaks according to the invention;

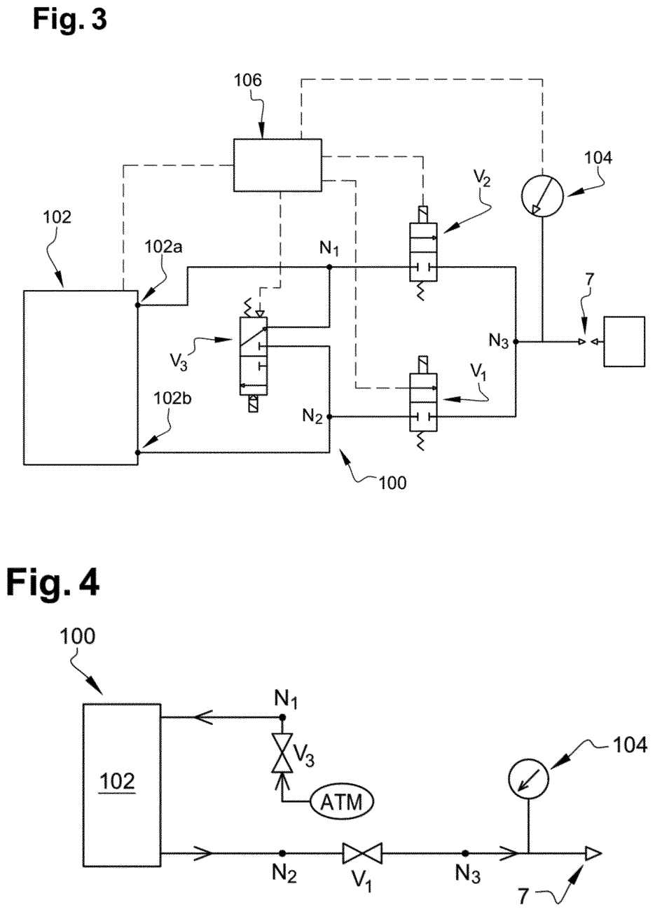

FIG. 3, labelled [FIG. 3], is a very schematic view of the pneumatic circuit of the device of FIGS. 1 and 2;

FIG. 4, labelled [FIG. 4], is a schematic view of the configuration of the circuit of FIG. 3 during a step of starting the device;

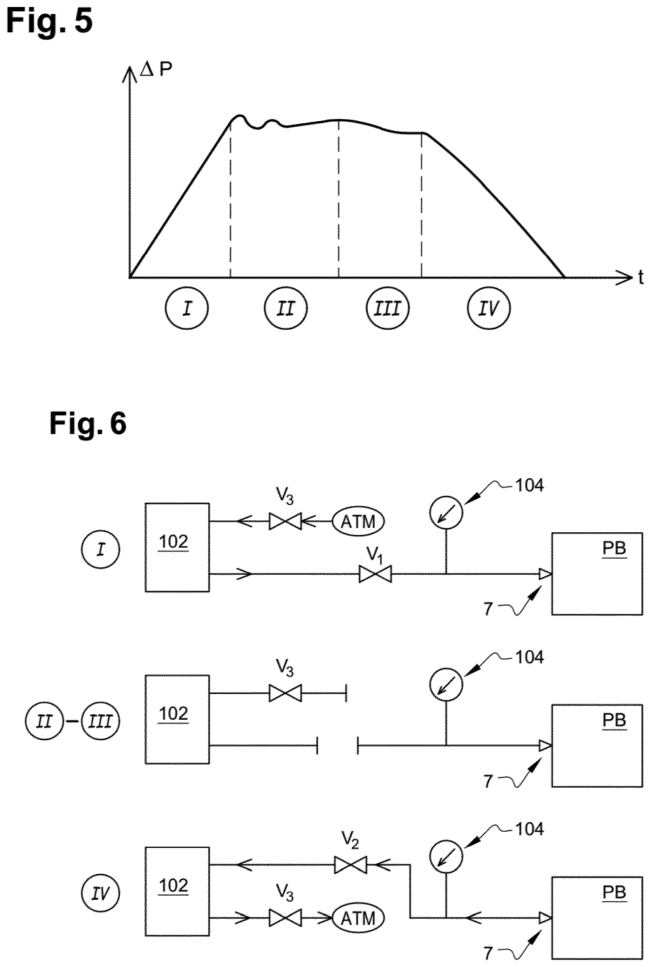

FIG. 5, labelled [FIG. 5], is a graph illustrating an example of variation in the pressure during a procedure for detecting leaks carried out by the device of FIGS. 1 and 2;

FIG. 6, labelled [FIG. 6], illustrates the various configurations of the circuit of FIG. 4 during the various steps of a detection of leaks, under pressure, carried out via said device of FIGS. 1 and 2;

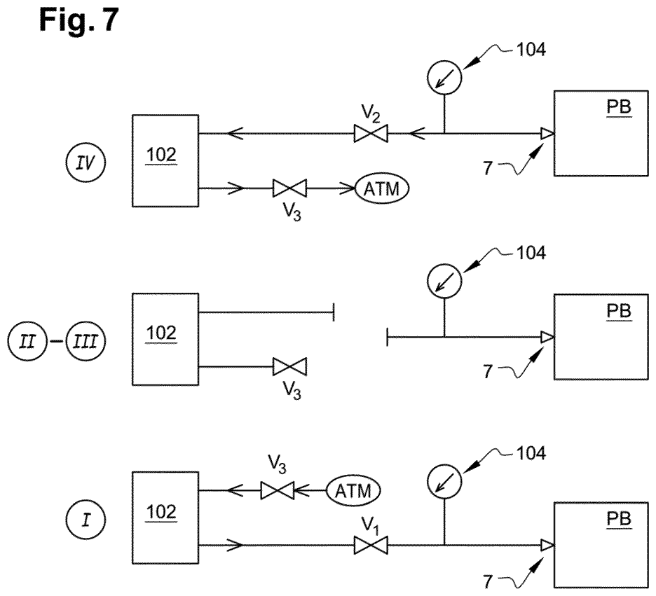

FIG. 7, labelled [FIG. 7], illustrates the various configurations of the circuit of FIG. 4 during the various steps of a detection of leaks, under vacuum, carried out via said device of FIGS. 1 and 2;

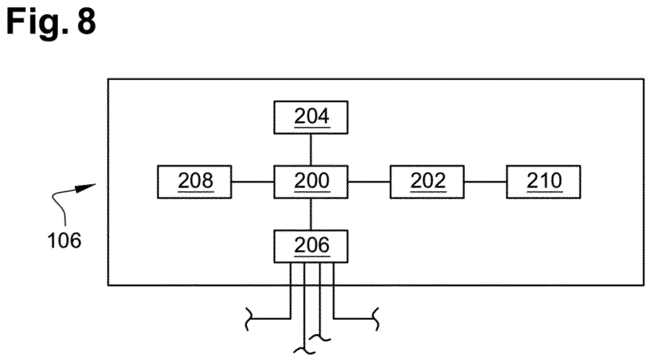

FIG. 8, labelled [FIG. 8], is a very schematic view of a module for controlling the pneumatic circuit of FIG. 4.

FIG. 1 and [FIG. 2] are very schematic perspective views, respectively front and rear, of a device 1 for detecting leaks for a motor vehicle battery pack.

The device 1 for detecting leaks is a device allowing to test the sealing of at least one battery pack element by variation of pressure. That is to say that the device is configured to carry out a procedure for detecting leaks in which there is a variation of the pressure in the element tested (either by increasing it or by decreasing it) to a predetermined pressure value, then after a defined time, there is a measurement of the pressure. A variation in pressure between this predetermined value and the final pressure value thus indicates that the element tested has a leak, the device 1 being configured to determine a leak rate according to this change in pressure over time.

“Battery pack” means the traction and/or operating batteries generally disposed in a case and accompanied by a thermal management system, this assembly forming a battery pack intended to be on board both electric and hybrid vehicles. As for said thermal management system, it comprises for example a network of fluid ducts allowing to cool or to heat the battery.

It is noted that detecting leaks in a battery pack is equivalent to testing the sealing (or the level of leaks) of the case and/or of the thermal management system of the battery.

The volume of the battery case generally has a volume of between 50 and 300 litres, while the volume of the thermal management system generally has a volume of between 10 and 50 litres.

Said device 1 comprises in particular a case 3 and a man-machine interface 5 (also designated by the term “MMI” below).

Said man-machine interface 5 (or user interface) allows, inter alia, to start the device 1, and the user to select the operating mode in which the device 1 must be used, for example for a test of leaks of the battery case or of a battery thermal management system. The interface 5 can thus allow to select a procedure for detecting leaks (or procedure for testing sealing) according to the battery pack to be tested.

It is noted that man-machine interface 5 means all of the elements allowing the user to interact with the device 1, and more particularly to control the device 1 and/or exchange information with the latter. The man-machine interface 5 comprises for example one or more of the following elements: button(s), keyboard, screen, touch screen, wheel(s), light indicators, etc.

However, in the embodiment illustrated in [FIG. 1] and [FIG. 2], the man-machine interface 5 includes a touch screen 5a, as well as a communication port 5b, for example of the USB type. The communication port 5b allows in particular to be able to connect to said device 1 via a third-party apparatus (for example to recover data, update the device, etc.).

As for said case 3, it has for example a substantially parallelepipedic shape, as well as a front face 3a, a rear face 3b, a lower face 3c, an upper face 3d and lateral faces 3e.

Said case 3 also includes support feet 31, at least one winding support 33 and a gripping handle 35.

Each of the support feet 31 includes magnets (not shown), the latter allowing in particular to secure the device 1 to a (ferromagnetic) surface during its use and avoid its inadvertent movement for example after a collision or any other external cause.

Said support feet 31 each include two parts here, a lug 31a (for example metal) connected to the case 3 (at its lower face 3c) and a pad 31b disposed on the distal end of said lug 31a. Said pads 31b thus comprise one or more magnets for example overmoulded, said pads 31b generally being made of plastic material, made of polymer or an analogous material. Said magnetised pads 31b thus allow to rigidly secure the device 1 onto a metal surface, in particular during a procedure for detecting leaks.

The support feet 31 are advantageously configured so that the device 1 has an inclination, for example of between 10 and 30 degrees with respect to the surface (generally horizontal) on which the device 1 is placed. Thus, the front of the device 1 is raised with respect to the rear, thus facilitating the access for the operator to the man-machine interface 5 and more generally simplifying the use of the device 1.

In an alternative embodiment not shown, only the man-machine interface 5, more particularly the screen 5a, has an inclination, for example of between 10 and 30 degrees.

As for the winding support 33, it is configured to allow the winding of a power supply cable and/or of a test duct, such as a flexible air duct. Said winding support 33 comprises for example two protrusions 33a (or tubes, protuberances, etc.) at a distance from one another, preferably disposed on one of the lateral faces 3e of said device 1.

The gripping handle 35 is preferably disposed on the upper face 3d of the case 3 and facilitates in particular the movement of the device 1 to the location of its use and/or the disconnection of the support feet 31 from the surface on which the feet 31 are magnetised.

Said case 3 can also comprise one or more antishock protections 37, for example disposed on the corners of the case 3 (in particular at the front 3a and rear 3b faces), to protect the device and/or the operator in the case of impacts. Said protections 37 are for example made of plastic material, made of rubber, etc., and are in the form of bands surrounding the perimeter (or contour) of the case 3 (while covering said corners of the case).

Said device 1 also comprises a test connector 7 intended to be connected (for example by the test duct) to the battery pack to be tested. Said test connector is for example disposed on the rear face 3b of said device 1. The test duct which allows to connect the device 1 to the battery pack (that is to say to the case of the battery and/or thermal management system) comprises a suitable connector.

Said device 1 further comprises a power supply plug 39 allowing to connect the device 1 to the power grid, as well as an On/Off button 41 allowing to turn on or turn off the device 1. The power supply plug 39 and the button 41 are advantageously disposed on the rear face 3e of the device 1.

The device 1 according to the invention also comprises a pneumatic circuit 100, a circuit more particularly illustrated in [FIG. 3], said circuit 100 is configured to place the element of the battery pack, the sealing of which must be tested, under pressure or under vacuum.

Said pneumatic circuit 100 thus comprises:
a pump 102 (or a compressor), for example of the volumetric type, configured to place the object, the sealing of which it is desired to test (and thus connected to the pump 102 via the connector 7 and said circuit 100), under pressure or under vacuum;
a plurality of valves V₁, V₂ and V₃, said valves being configured to allow in particular the filling and/or emptying of at least one element of the battery pack;
a pressure sensor 104, for example an absolute pressure sensor.

Said elements of said circuit are connected to each other via suitable ducts.

Said valves V₁ and V₂, respectively first and second valve, are for example 2/2 directional control valves (or one-way valve), whereas the valve V₃, or third valve, is for example a 3/2 directional control valve (or two-way valve).

The valves V₁ and V₂ thus have two positions, open or closed, that is to say two orifices and allowing the circulation of fluid between the two orifices of said valves or not.

While the valve V₃ has three orifices and two positions, in the present case the first and second orifices are connected to said circuit 100 and the third orifice is connected to the atmosphere. Thus according to the position of the valve, the first or second orifice is connected to the third, while the remaining orifice is closed.

The pump 102 comprises an inlet or suction orifice 102a, as well as an outlet or discharge orifice 102b. The inlet 102a of the pump 102 is connected directly to the valves V₂ and V₃ while the outlet 102b is connected directly to the valves V₁ and V₃.

More particularly, the inlet 102a is connected to a first node N₁ which is itself connected to a first orifice of the valve V₃ and to a first orifice of the valve V₂. The outlet 102b is connected to a second node N₂ which is itself connected to a second orifice of the valve V₃ and to the first orifice of the valve V₂ (the valve V₃ is thus disposed in parallel to the valves V₁ and V₂). As for the second orifices of the valves V₂ and V₃, they are connected to a third node N₃. The node N₃ is connected to the connector 7 and the pressure sensor 104 is disposed on the duct between the node N₃ and said connector 7.

Said circuit 100 also comprises at least one control module 106 configured, inter alia, to control the elements of the pneumatic circuit 100 (the pump 102, the valves V₁-3, etc.). Said control module 106 comprises for example one or more electronic cards.

The various steps of a sealing test are described in detail below, but the device 1 is also configured to carry out a procedure for setting to zero (or auto-zero) the pressure at the pressure sensor 104 during the starting of said device 1.

Thus, during the procedure for setting to zero, there is activation of the pump 102 and opening of the valve V₁, while the first node N₁ is connected to the atmosphere, and the connection of the second node N₂ to the valve V₃ is closed. The equivalent diagram of the circuit 100 during this procedure is more particularly illustrated in [FIG. 4].

The pump 102 thus sucks up air via the valve V₃ (thus generating creation of a vacuum) and engenders an overpressure at the outlet 102b that propagates to the connector 7. This allows to verify that the pressure sensor 104 is working and that the device 1 is not yet connected to an element of a battery pack. This also allows to purge a part of the circuit 100, more particularly the part to which said pressure sensor 104 is connected.

Said device 1 is also configured to include a self-test procedure. Said self-test procedure allows to verify the presence of leaks in the device 1, in particular at the circuit 100 and in a test duct. During a self-test procedure, the test outlet of the circuit 100 (with or without test duct connected to the connector 7) is closed by a plug. A procedure for detecting leaks is then triggered, under pressure and/or under vacuum, to verify that there are no leaks in the circuit and/or in the test duct that could distort the detection of leaks in an element of a battery pack.

The device 1 for detecting leaks is a device allowing to test the sealing of at least one battery pack element by variation of pressure. That is to say that the device is configured to carry out a procedure for detecting leaks in which there is a variation of the pressure in the element tested (either by increasing it or by decreasing it) to a predetermined pressure value, then after a defined time there is a measurement of the pressure. A variation in pressure between this predetermined value and the final pressure value thus indicates that the element tested has a leak, the device 1 being configured to determine a leak rate according to this change in the pressure over time.

FIG. 5 is a graph illustrating the various steps of a procedure for detecting leaks (under pressure) carried out by the device 1 according to the invention.

There are thus 4 steps respectively labelled I, II, III and IV:
step I is the filling step, that is to say that the pressure in the element of the battery pack tested is increased until a determined pressure value is reached.
Step II is the stabilisation step, indeed the increase in the pressure in the element leads to variations in temperature, thermal exchanges, etc. that can disturb the measurement, it is therefore necessary to wait for a predetermined time t_{stab} for the transient phenomena that can disturb the measurement to abate.
Step III is the measurement step, the measurement of variation in the pressure during this step allows the device 1 to calculate a leak rate (for example in cubic centimetres per minute) and to determine whether the element tested has a leak.
Step IV is the emptying step, the device 1 is configured in order for the pressure of the element tested to go back to a pressure value substantially close to the atmospheric pressure, in order for the device 1 to be able to be disconnected without risk to the operator.

It is noted that the procedure for detecting leaks can also be carried out under vacuum (or depression), that is to say that instead of increasing the pressure during the first step, the pressure in the element to be tested is decreased to a predetermined value. Steps II and III remain unchanged. While the fourth step involves increasing the pressure in the element tested to a pressure value corresponding to the atmospheric pressure. There is therefore an “inversion” of the filling and emptying steps I and IV between the procedures for detecting leaks under pressure and under vacuum.

Thus, the device 1 is configured to carry out procedures for detecting leaks in two different modes, a first pressure (or overpressure) mode and a second vacuum (or depression) mode.

FIG. 6 shows the equivalent configuration of the pneumatic circuit 100 according to the steps of a detection procedure according to the first mode.

Thus, when the device 1 tests the sealing of an object PB, such as a battery pack, under pressure, the procedure for detecting leaks includes the steps described below, with the configurations of the circuit 100 described below.

There is a step of filling I of the object PB by the pump 102. For this, the valve V₃ connects the inlet of the pump 102 to the atmosphere. While the valve V₁ connects the outlet of the pump 102 to the object PB, via the connector 7. The device 1 increases the pressure inside the object PB to a predetermined value, the sensor 104 allowing to measure the value of the pressure and to order the stopping of the pump 102 when the desired pressure value is reached.

There are then the steps of stabilisation and testing, II and III, in which the pump 102 is turned off, while the valves V₁ and V₂ are closed. The steps of stabilisation and testing each respectively have a predetermined duration depending on the element and the battery pack tested, respectively t_{stab} and tₜₑₛₜ. The variations in pressure measured by the sensor 104 during the testing step allow the device 1 to determine a leak rate relative to the object PB tested.

Then, the procedure for detecting leaks according to a first mode ends by an emptying step IV, a step during which the device 1 is configured to bring the pressure in the object PB to a pressure value close to the atmospheric pressure (or a pressure value compatible with the disconnection, without danger for the operator, of the test duct from the battery pack).

The valve V₁ is closed and the valve V₂ connects the object PB tested to the inlet of the pump 102. While the outlet of the pump 102 is connected to the atmosphere via the valve V₃. In this configuration, the activation of the pump 102 allows to evacuate the air (generating an overpressure) contained in the object PB tested.

FIG. 7 shows the equivalent configuration of the pneumatic circuit 100 according to the steps of a detection procedure according to the second mode.

Thus, when the device 1 tests the sealing of an object PB, such as a battery pack, under vacuum, the procedure for detecting leaks includes the steps described below with the configurations of the circuit 100 described below.

There is a step IV of emptying of the object PB by the pump 102. For this, the valve V₃ connects the outlet of the pump 102 to the atmosphere. While the valve V₂ connects the outlet of the pump 102 to the element PB, via the connector 7. The device 1 reduces the pressure inside the element PB to a predetermined value, the sensor 104 allowing to measure the value of the pressure and order the stopping of the pump 102 when the desired pressure value is reached.

There are then the steps of stabilisation and testing, II and III, in which the pump 102 is turned off, while the valves V₁ and V₂ are closed. The steps of stabilisation and testing each respectively have a predetermined duration, respectively t_{stab} and tₜₑₛₜ. The variations in pressure measured by the sensor 104 during the testing step allow the device 1 to determine a leak rate relative to the object PB tested.

Then, the procedure for detecting leaks according to a second mode ends by a filling step I, a step during which the device 1 is configured to increase the pressure in the object PB to a pressure value close to the atmospheric pressure.

The device 1 is thus configured to operate procedures for detecting leaks according to various modes, this is in particular carried out via the control module 106.

Said control module 106, more particularly illustrated in [FIG. 8], comprises:
a microprocessor 200;
a memory 202 for storing data, such as a random-access memory and a non-volatile memory;
a communication module 204 for communicating with remote entities, computers, servers, etc.;
a control module 206 connected to the valves V₁ to V₃, to the pump 102 and to the pressure sensor 104, said module 206 being configured to control the valves and the pump, but also to recover the values of the measurements carried out by various sensors, in particular from the pressure sensor 104 or from environment sensors (temperature, humidity, atmospheric pressure, etc.).

Said module 106 can also comprise an electric power supply 206 either autonomous or connected to the grid (in particular via the electric plug 39) and configured to convert the input current and voltage into values compatible with the various elements of the module 106 and/or of the device 1.

Said module 106 is also connected to the man-machine interface 5 (link not shown) and carries in the memory 202 an operating system managing in particular the interface displayed on the screen 5a.

Moreover, said device 1 comprises a database 210, in particular stored in the memory 202, relative to the battery packs and to the various relevant parameters for carrying out a procedure for detecting leaks adapted to the battery pack to be tested (for example under vacuum or under pressure).

Said database 210 thus comprises a list of motor vehicle models and/or battery pack models in which each model (of battery pack and/or of motor vehicle) is associated with a procedure for detecting leaks. The database 210 comprises for example for each battery pack listed at least one procedure for detecting leaks specific to each of the elements of a battery pack.

Each of the specific procedures for detecting leaks thus comprises leak thresholds allowing the device 1 to determine whether or not the battery pack has a leak.

Each of the procedures for detecting leaks can thus comprise one or more of the following parameters: volume of the battery and/or of the thermal management system of the battery pack, duration t_{stab} and tₜₑₛₜ of the various steps of the leak test, test pressure, speed of filling and/or of emptying of the element of the battery pack tested, leak threshold.

In an alternative embodiment, said database comprises a flexibility or elasticity coefficient associated with at least one element of the battery pack (case and/or thermal management system). The flexibility coefficient is for example a function V (P, t) linking the variation in the volume V of the element tested over time t and/or according to the pressure P, this reflects the tendency of the element to vary in volume during a procedure for detecting leaks. This function is all the more relevant to memories (and to determine) since it is specific to each battery model and it can have a non-linear nature (because for example of the geometry and/or of specific components of the battery pack).

Indeed, during a detection of leaks on an object, the volume of which is made to vary during the test (under the effect of a variation in pressure), this leads to difficulties in obtaining a correct measurement of the leak level.

Indeed, the variation in the volume can have consequences on the duration of the test, complicate the measurement of the leak and reduce the sensitivity, the volume, the pressure and the quantity of matter in the object tested being made to vary (these various values being linked to each other by the ideal gas law), and moreover the starting volume of the object also depends on the atmospheric pressure.

Moreover, it is noted that in an alternative embodiment, one or more devices 1 can be connected to a computer network, for example the local network of a repair centre. A device according to the invention can in particular clone and/or broadcast the parameters of its database to the other devices connected to the same computer network.

In another alternative embodiment not illustrated, the pneumatic circuit of the device according to the invention comprises at least one flow limiter.

Advantageously, said at least one flow limiter is disposed between the node N₃ and the pressure sensor 104. Thus, a single flow limiter suffices to limit the flow rate in the pneumatic circuit, regardless of the procedure for detecting leaks carried out by the device 1. In an alternative embodiment, each of the branches of the pneumatic circuit including a 1-way valve V₁ or V₂ comprises a flow limiter.

The flow limiter allows in particular the device according to the invention to vary the pressure in the object tested more finely, and thus to have a real pressure close to the desired pressure.

The flow limiter is for example configured to have a maximum flow rate of 24 standard.litres/min, or 0.4 standard.litres/sec. However, it is advantageous for the maximum flow rate of the flow limiter to be less than the maximum flow rate of the pump of the pneumatic circuit (the flow limiter must thus be chosen according to the capability of the pump).

Said device 1 can also be configured to measure the back pressure value relative to the battery pack tested. The measurement of the back pressure value is carried out at the beginning of the filling (or of the emptying) of the part tested, thus at the beginning of the procedure for detecting leaks.

More particularly, there is a measurement of the pressure before and after activation of the pump (but after the suitable control of the valves V₁-3), the difference in these measurements of pressure giving the value of the back pressure.

In other words, there is a measurement of the pressure at the moment at which the part is still empty, or during the filling.

It is noted that back pressure means the resistance or the force opposing the desired flow of a fluid in ducts or a circuit, which leads to a loss via friction and a drop in pressure.

Said device 1 is in particular configured for the back pressure value measured to be taken into account during the filling/emptying of the parts tested. The pressure value displayed by the MMI 5 (and measured by the sensor 104) is thus the value corrected by the back pressure value, a corrected value thus corresponding to the real pressure value.

Said device 1 is also configured to communicate, for example via the communication module 204, with a remote server, in particular to download on a remote server one or more of the following pieces of data: the results of the leak tests and/or the measurement signals of the leak tests.

All of the data downloaded from the remote server can in particular be used for the quality monitoring of the measurements and/or of the battery packs tested. Said downloaded data can also be used in the context of a “machine learning”, in particular to optimise the procedures for detecting leaks (for example by reducing or optimising the stabilisation and/or testing time, the test pressure values, the filling speeds, etc.).

The parameters thus modified can then be downloaded by the device according to the invention in order for the database relative to the procedures for detecting leaks to be updated.

1. Device (1) for detecting leaks for a motor vehicle battery pack, said device comprising:
a pneumatic circuit (100) comprising a plurality of valves (V₁, V₂, V₃), a pressure sensor (104) and a pump (102);
at least one connector (7) allowing to connect said pneumatic circuit (100) to at least one element of the battery pack;
said pneumatic circuit (100) being configured to operate at least one procedure for detecting leaks under pressure and/or under vacuum on at least one element of said battery pack.

2. Device (1) according to claim 1, characterised in that it is configured to generate a relative pressure ranging from −1 to 3 bar.

3. Device (1) according to any one of the preceding claims, characterised in that the device (1) comprises a man-machine interface (5).

4. Device (1) according to the preceding claim, characterised in that said device (1) is configured to have an inclination with respect to the surface on which the device is placed so that the man-machine interface (5) is oriented upwards.

5. Device (1) according to the preceding claim, characterised in that the angle of inclination is between 10 and 30 degrees.

6. Device (1) according to any one of the preceding claims, characterised in that said device (1) comprises at least one magnetised support foot (31).

7. Device (1) according to any one of the preceding claims, characterised in that said device (1) comprises at least one winding support (33).

8. Device (1) according to any one of the preceding claims, characterised in that said pneumatic circuit (100) comprises two one-way valves (V₁ and V₂), as well as a two-way valve (V₃).

9. Device (1) according to any one of the preceding claims, characterised in that the pneumatic circuit (100) comprises at least one flow limiter.

10. Device (1) according to any one of the preceding claims, characterised in that it is configured to measure and take into account the value of the back pressure during a procedure for detecting leaks in at least one element of said battery pack.
